(19) United States
(12) Patent Application Publication
(10) Pub. No.: US 2015/0270268 A1
(43) Pub. Date: Sep. 24, 2015

(54) SEMICONDUCTOR DEVICE

(71) Applicant: Atsushi Fujikawa, Tokyo (JP)

(72) Inventor: Atsushi Fujikawa, Tokyo (JP)

(21) Appl. No.: 14/440,964

(22) PCT Filed: Oct. 21, 2013
(86) PCT No.: PCT/JP2013/078437

§ 371 Date: May 6, 2015

(30) Foreign Application Priority Data
Nov. 6, 2012 (JP) 2012-244448

(51) Int. Cl. H01L 27/092; H01L 29/10; H01L 29/06; H01L 29/78; H01L 29/417

(52) U.S. Cl. CPC H01L 27/0922; H01L 29/7827; H01L 29/41741; H01L 29/41766; H01L 29/0653; H01L 29/1037

(57) ABSTRACT

The present invention is provided with: a plurality of pillars vertically arranged on a semiconductor substrate; a plurality of second diffusion layers respectively arranged on the upper part of each pillar; a conductive layer electrically connected to at least one of the second diffusion layers; and at least one contact formed on at least one of the plurality of second diffusion layers, the number of electrical connections (contacts) between the second diffusion layers and the conductive layer being smaller than the number of pillars, and the number of connections between the pillars and the conductive layer being changeable as needed.

### TECHNICAL FIELD

The present invention relates to a semiconductor device; and more particularly, to a semiconductor device having a pillar insulated gate field-effect transistor.

### BACKGROUND ART

The area occupied by a conventional planar transistor on a substrate requires at least a channel area of the gate length×the channel width, source/drain diffusion layers and an electrode lead-out contact layout for these layers, and element isolation regions between transistors.

A three-dimensional transistor instead of a planar transistor has been proposed to make the dedicated area smaller. Among such, a pillar insulated gate field-effect transistor (MOSFET) is effective for making the dedicated area smaller (see, for example, Patent Document 1).

### PATENT DOCUMENT

Patent Document 1: Japanese Unexamined Patent Publication No. 2009-081377

### OUTLINE OF THE INVENTION

### Problems that the Invention is to Solve

Transistor characteristics generally must be adjusted to adjust circuit characteristics or absorb manufacturing irregularities. Therefore, extra transistors have been arranged in advance, and the number of transistor connections have been modified in the layout process to adjust electrical characteristics. Because one transistor in a planar transistor requires the occupied area described earlier, preparing extra transistors has led to an increased chip size.

Therefore, a semiconductor device which facilitates adjusting transistor characteristics would be desirable for a pillar MOSFET, which is useful for making the dedicated area smaller.

### Means of Solving the Problems

An embodiment of the present invention provides a semiconductor device characterized in that the device is provided with at least two pillar transistors raised in mutually isolated element regions on a semiconductor substrate;

the two pillar transistors have
the same number of two or more pillars in each of the element isolated regions;
a diffusion layer arranged on an upper portion of each of the pillars; and
a conductive layer electrically connected to the diffusion layer in each of the element isolated regions;
and the two pillar transistors differ from each other in the number of diffusion layers electrically connected to the conductive layer.

Another embodiment of the present invention provides

a semiconductor device characterized in that the device is provided with a plurality of pillar transistors raised on a semiconductor substrate;
a plurality of source regions, a plurality of channel regions, and a plurality of drain regions comprising each of the plurality of pillar transistors;
a source electrode for connecting to each of the plurality of source regions;
a gate electrode for simultaneously driving each of the channel regions;
a drain electrode connected through a contact to a portion of the plurality of drain regions; and
at least one drain region of the plurality of drain regions for opposing the drain electrode not through the contact, but through an insulating layer.

Still another embodiment provides

a semiconductor device characterized in that the device is provided with a plurality of pillar transistors raised on a semiconductor substrate;
each of the plurality of pillars has a lower portion, an upper portion, and sides; the device is provided with a first diffusion layer for connecting to each of the lower portions;
a plurality of second diffusion layers arranged on each of the upper portions; a gate electrode comprising a connector and opposing a gate insulating film on each of the sides;
a conductive layer electrically connected to one or more of the plurality of second diffusion layers; and
one or more contacts formed on one or more the plurality of second diffusion layers;
and the number of electrical connections between the second diffusion layers and the conductive layer is less than the number of the pillars.

### Effects of the Invention

According to the embodiments of the present invention, the number of parallel-connected pillar transistors can be easily modified, making a quick-delivery design possible, even in the case that transistor characteristics must be corrected after the actual device has been manufactured.

### BRIEF EXPLANATION OF THE DRAWINGS

FIG. 1A shows a plan view of the main components of a semiconductor device according to an embodiment example of the present invention;

FIG. 1B shows a sectional view taken at X1-X1′ in FIG. 1A;

FIG. 1C shows a sectional view taken at X2-X2′ in FIG. 1A;

FIG. 1D shows a sectional view taken at Y-Y′ in FIG. 1A;

FIG. 2A shows a plan view of the manufacturing process of a semiconductor device according to an embodiment example of the present invention;

FIG. 2B shows a sectional view taken at X1-X1′ in FIG. 2A;

FIG. 2C shows a sectional view taken at X2-X2′ in FIG. 2A;

FIG. 2D shows a sectional view taken at Y-Y′ in FIG. 2A;

FIG. 3A shows a plan view of the manufacturing process of a semiconductor device according to an embodiment example of the present invention;

FIG. 3B shows a sectional view taken at X1-X1′ in FIG. 3A;

FIG. 3C shows a sectional view taken at X2-X2′ in FIG. 3A;

FIG. 3D shows a sectional view taken at Y-Y′ in FIG. 3A;

FIG. 4A shows a plan view of the manufacturing process of a semiconductor device according to an embodiment example of the present invention;

FIG. 4B shows a sectional view taken at X1-X1′ in FIG. 4A;

FIG. 4C shows a sectional view taken at X2-X2′ in FIG. 4A;

FIG. 4D shows a sectional view taken at Y-Y′ in FIG. 4A;

FIG. 5A shows a plan view of the manufacturing process of a semiconductor device according to an embodiment example of the present invention;

FIG. 5B shows a sectional view taken at X1-X1′ in FIG. 5A;

FIG. 5C shows a sectional view taken at X2-X2′ in FIG. 5A;

FIG. 5D shows a sectional view taken at Y-Y′ in FIG. 5A;

FIG. 6A shows a plan view of the manufacturing process of a semiconductor device according to an embodiment example of the present invention;

FIG. 6B shows a sectional view taken at X1-X1′ in FIG. 6A;

FIG. 6C shows a sectional view taken at X2-X2′ in FIG. 6A;

FIG. 6D shows a sectional view taken at Y-Y′ in FIG. 6A;

FIG. 7B shows a sectional view taken at X1-X1′ in the process after FIG. 6;

FIG. 7C shows a sectional view taken at X2-X2′ in the process after FIG. 6;

FIG. 7D shows a sectional view taken at Y-Y′ in the process after FIG. 6;

FIG. 8A shows a plan view of the manufacturing process of a semiconductor device according to an embodiment example of the present invention;

FIG. 8B shows a sectional view taken at X1-X1′ in FIG. 8A;

FIG. 8C shows a sectional view taken at X2-X2′ in FIG. 8A;

FIG. 8D shows a sectional view taken at Y-Y′ in FIG. 8A;

FIG. 9A shows a plan view of the manufacturing process of a semiconductor device according to an embodiment example of the present invention;

FIG. 9B shows a sectional view taken at X1-X1′ in FIG. 9A;

FIG. 9C shows a sectional view taken at X2-X2′ in FIG. 9A;

FIG. 9D shows a sectional view taken at Y-Y′ in FIG. 9A;

FIG. 10A shows a plan view of the manufacturing process of a semiconductor device according to an embodiment example of the present invention;

FIG. 10B shows a sectional view taken at X1-X1′ in FIG. 10A;

FIG. 10C shows a sectional view taken at X2-X2′ in FIG. 10A;

FIG. 10D shows a sectional view taken at Y-Y′ in FIG. 10A;

FIG. 11A shows a plan view of the manufacturing process of a semiconductor device according to an embodiment example of the present invention;

FIG. 11B shows a sectional view taken at X1-X1′ in FIG. 11A;

FIG. 11C shows a sectional view taken at X2-X2′ in FIG. 11A;

FIG. 11D shows a sectional view taken at Y-Y′ in FIG. 11A;

FIG. 12A shows a plan view of the manufacturing process of a semiconductor device according to an embodiment example of the present invention;

FIG. 12B shows a sectional view taken at X1-X1′ in FIG. 12A;

FIG. 12C shows a sectional view taken at X2-X2′ in FIG. 12A;

FIG. 12D shows a sectional view taken at Y-Y′ in FIG. 12A;

FIG. 13B shows a sectional view taken at X1-X1′ in the process after FIG. 12;

FIG. 13C shows a sectional view taken at X2-X2′ in the process after FIG. 12;

FIG. 13D shows a sectional view taken at Y-Y′ in the process after FIG. 12;

FIG. 14A shows a plan view of the manufacturing process of a semiconductor device according to an embodiment example of the present invention;

FIG. 14B shows a sectional view taken at X1-X1′ in FIG. 14A;

FIG. 14C shows a sectional view taken at X2-X2′ in FIG. 14A;

FIG. 14D shows a sectional view taken at Y-Y′ in FIG. 14A;

FIG. 15A shows a plan view of the manufacturing process of a semiconductor device according to an embodiment example of the present invention;

FIG. 15B shows a sectional view taken at X1-X1′ in FIG. 15A;

FIG. 15C shows a sectional view taken at X2-X2′ in FIG. 15A;

FIG. 15D shows a sectional view taken at Y-Y′ in FIG. 15A;

FIG. 16A shows a plan view of the manufacturing process of a semiconductor device according to an embodiment example of the present invention;

FIG. 16B shows a sectional view taken at X1-X1′ in FIG. 16A;

FIG. 16C shows a sectional view taken at X2-X2′ in FIG. 16A;

FIG. 16D shows a sectional view taken at Y-Y′ in FIG. 16A;

FIG. 17A shows a plan view of the manufacturing process of a semiconductor device according to an embodiment example of the present invention;

FIG. 17B shows a sectional view taken at X1-X1′ in FIG. 17A;

FIG. 17C shows a sectional view taken at X2-X2′ in FIG. 17A;

FIG. 17D shows a sectional view taken at Y-Y′ in FIG. 17A;

FIG. 18 is a drawing illustrating a mode for controlling transistor characteristics by adjusting the number of contacts in an embodiment example of the present invention;

FIG. 19A shows a plan view of the manufacturing process of a semiconductor device according to another embodiment example of the present invention;

FIG. 19B shows a sectional view taken at X1-X1′ in FIG. 19A;

FIG. 19C shows a sectional view taken at X2-X2′ in FIG. 19A;

FIG. 19D shows a sectional view taken at Y-Y′ in FIG. 19A;

FIG. 20A shows a plan view of the manufacturing process of a semiconductor device according to still another embodiment example of the present invention;

FIG. 20B shows a sectional view taken at X1-X1′ in FIG. 20A;

FIG. 20C shows a sectional view taken at X2-X2′ in FIG. 20A; and

FIG. 20D shows a sectional view taken at Y-Y′ in FIG. 20A.

### EMBODIMENTS OF THE INVENTION

The present invention will be described in detail hereinafter by citing specific embodiment examples, but the present invention is not to be taken as limited to these embodiment examples.

### Embodiment Example 1

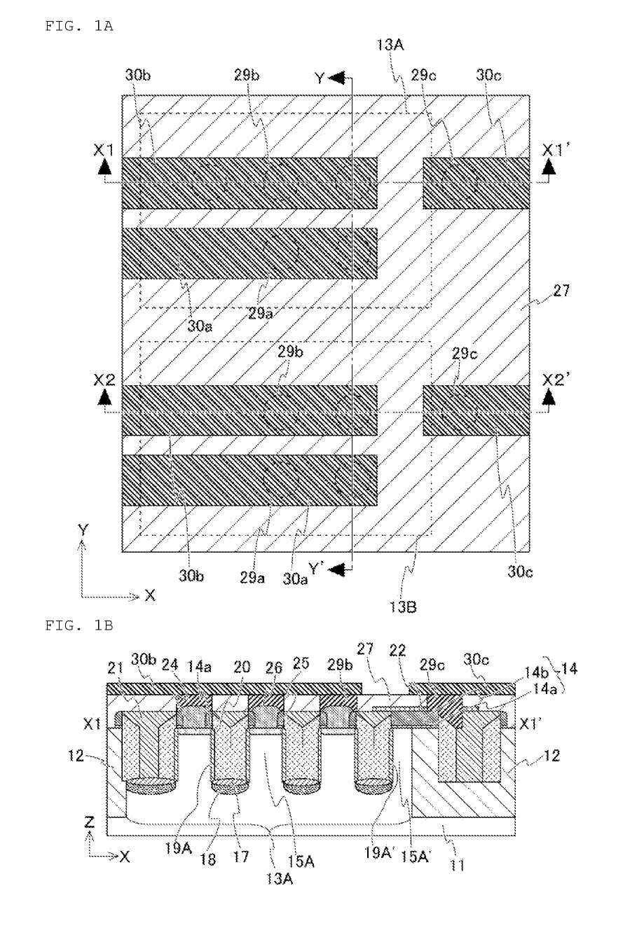

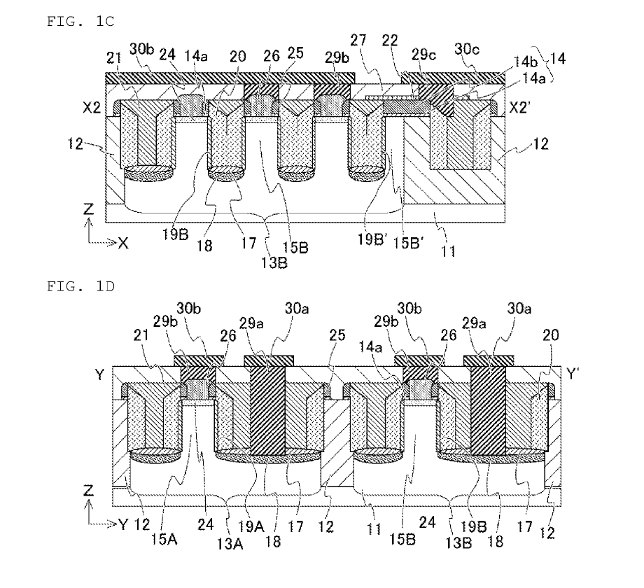

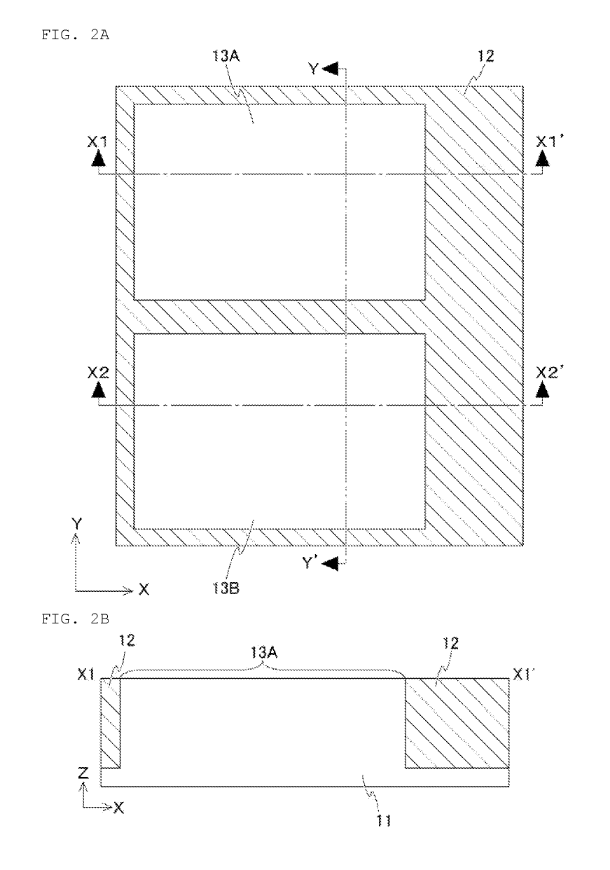

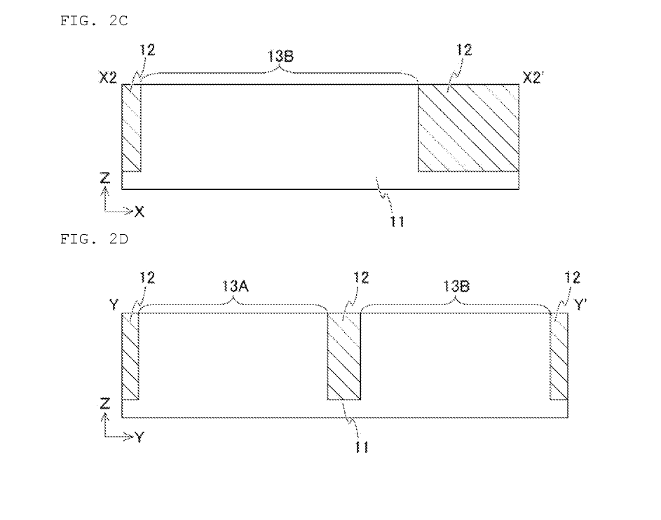

The configuration and effects of the semiconductor device according to the present embodiment example will be described using FIGS. 1 and 2.

FIG. 1A shows a plan view of the main components of a semiconductor device according to an embodiment example of the present invention. FIG. 1B shows a sectional view taken at X1-X1′ in FIG. 1A, FIG. 1C shows a sectional view taken at X2-X2′ in FIG. 1A, and FIG. 1D shows a sectional view taken at Y-Y′ in FIG. 1A. Although three pillars are arranged in one row in mutually isolated element active regions 13A and 13B, the embodiment is not limited to three pillars and one row. A first diffusion layer 18 is disposed in a lower portion of each pillar, a second diffusion layer 26 is disposed in an upper portion, and a portion surrounding a gate electrode 20 comprises a channel region. For convenience, the first diffusion layer 18 is assumed to be a source region and the second diffusion layer 26 is assumed to be a drain region. The source region of each of the active regions 13A and 13B is connected through a contact plug 29a to a layout comprising a source electrode 30a. As shown in FIG. 1B, a contact plug 29b is formed on the second diffusion layer 26 on every pillar 15A in the active region 13A, and is connected to a layout comprising a drain electrode 30b. As shown in FIG. 1C, a contact plug 29b is not disposed on one pillar of the three pillars 15B in the active region 13B, and one second diffusion layer 26 lies between an insulating film 27 and the layout comprising a drain electrode 30b. That is, where three pillars are parallel-connected in the active region 13A, two pillars of the three pillars are parallel-connected in the active region 13B. A transistor comprising pillars parallel-connected in one active region will sometimes be called a pillar transistor in the present invention. Thus, the pillar transistor A formed in the active region 13A has more parallel-connected pillars than the pillar transistor B formed in the active region 13B, and therefore can have a larger drive current.

Considering the pillar transistor B shown on the right side of FIGS. 1C and 1D, the plurality of pillars 15B comprise a plurality of pillar transistors provided with the first diffusion layer 18, which comprises a source region, and the second diffusion layer 26, which comprises a channel region and a drain region. The source regions below the pillar transistors are connected to each other to comprise the first diffusion layer 18, and the first diffusion layer 18 and the layout comprising a source region 30a are electrically connected through the contact 29a. The channel regions of the pillar transistors are driven simultaneously by the gate electrode 20. Each second diffusion layer 26 comprising a drain region is disposed above one of the pillar transistors, and a portion of the second diffusion layer 26 is connected through the contact 29b to the layout comprising a drain electrode 30b. The layout 30b opposes, through the insulating film 27, the second diffusion layer 26 where the contact 29b is not formed. The semiconductor device according to an embodiment of the present invention includes at least one pillar transistor in which the second diffusion layer 26 is not electrically connected to the layout 30b comprising a conductive layer. Considering the pillar transistor A shown on the left side of FIGS. 1B and 1D, this is a pillar transistor having at least two parallel-connected pillars. Therefore, the semiconductor device according to an embodiment of the present invention includes one or more parallel-connected pillar transistors.

Next, the configuration and manufacture of a semiconductor device according to the present embodiment example will be described in detail.

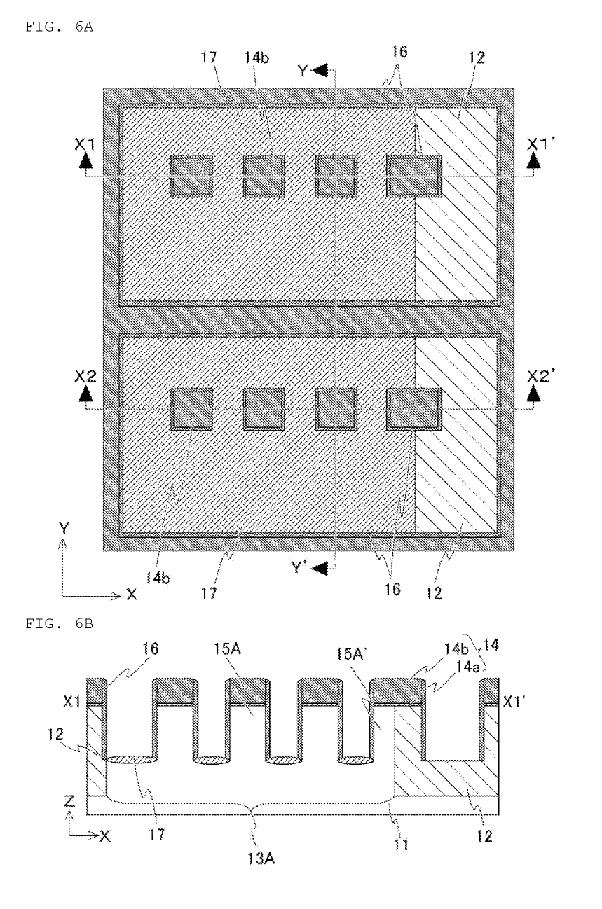

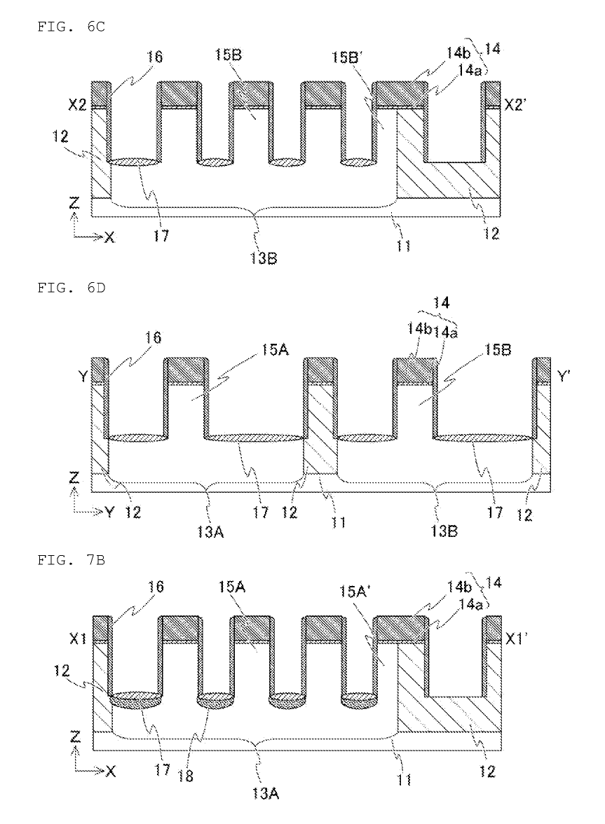

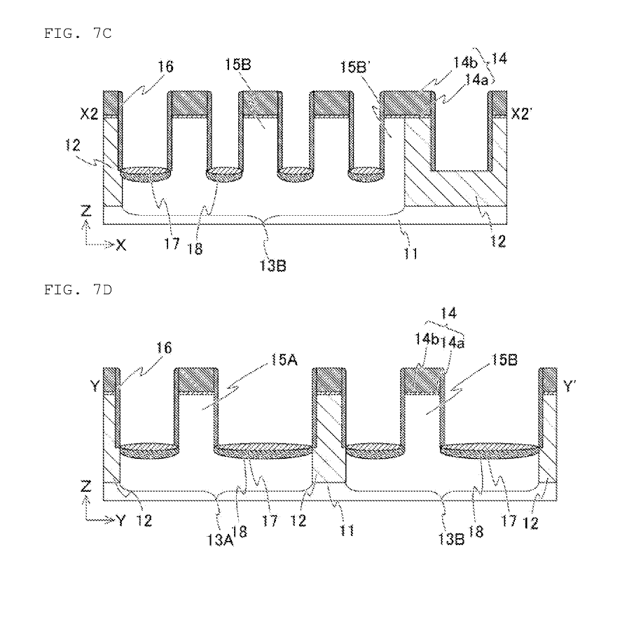

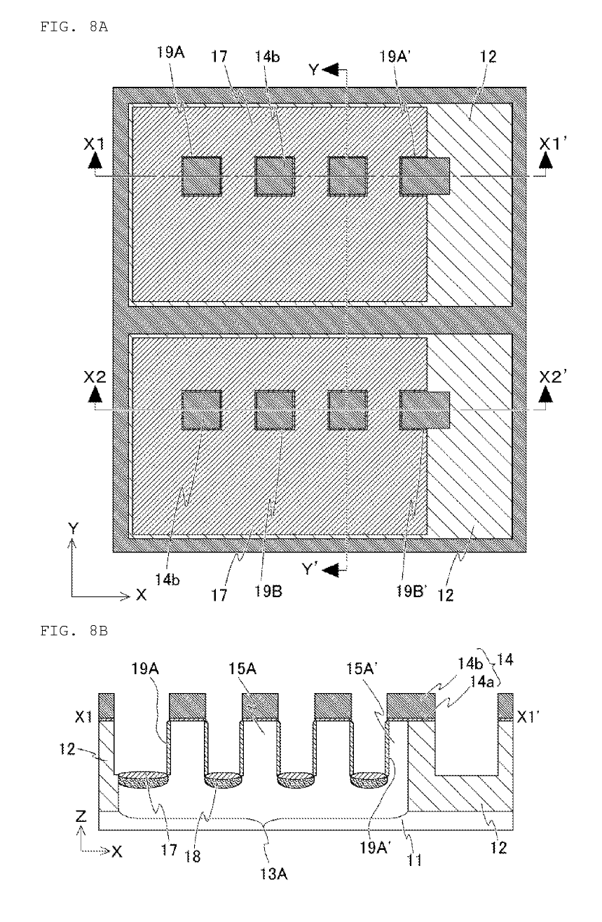

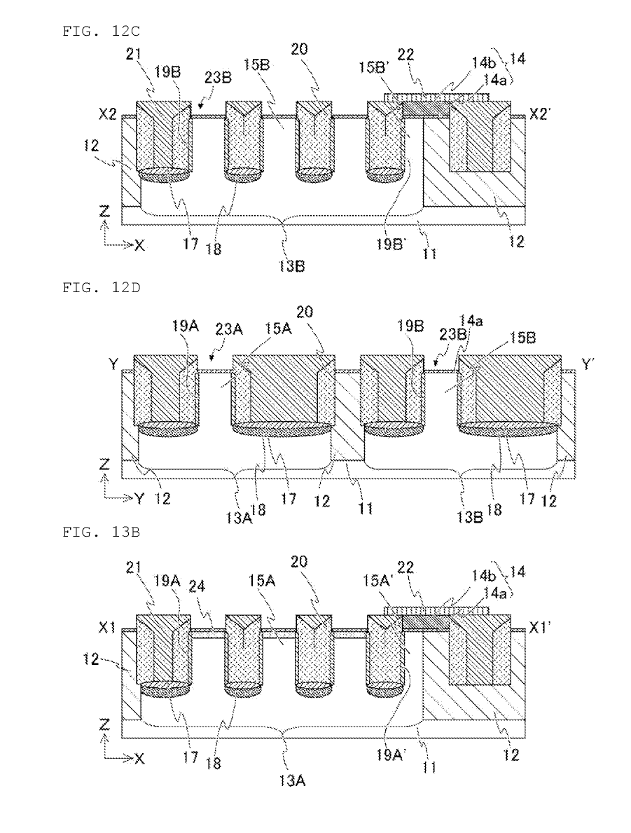

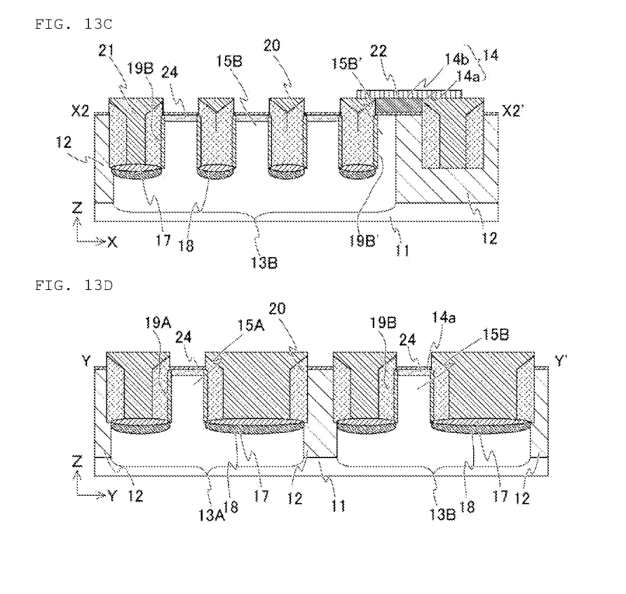

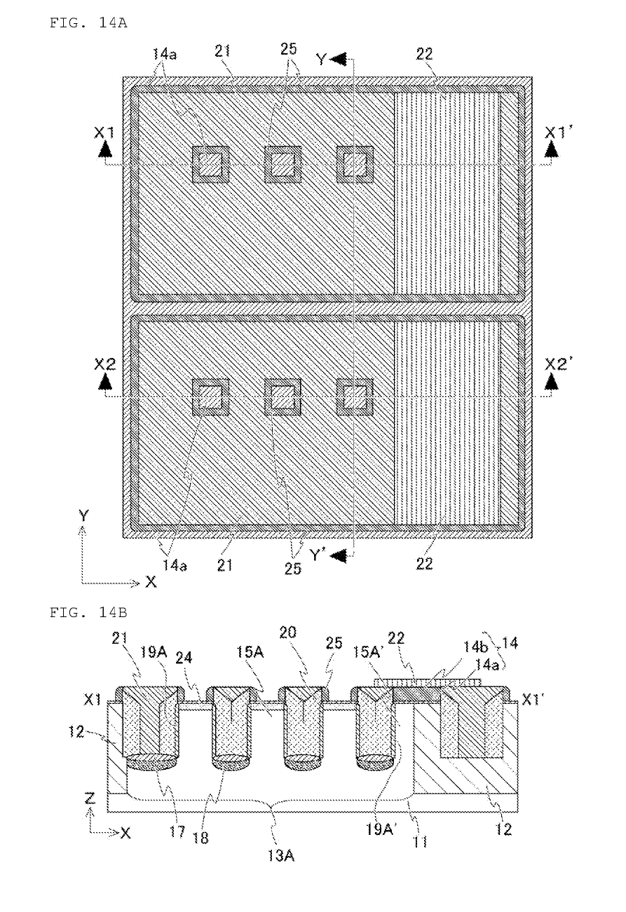

FIGS. 2-17 are process diagrams illustrating manufacture of the semiconductor device according to the present embodiment example, in which drawing A is a plan view, drawing B is a sectional view taken at X1-X1′ in drawing A, drawing C is a sectional view taken at X2-X2′ in drawing A, and drawing D is a sectional view taken at Y-Y′ in drawing A. FIGS. 7A and 13A are omitted because the processes in FIGS. 7 and 13 are the same in plan view as FIGS. 6A and 12A. In the following description, FIG. 2, for example, collectively indicates FIGS. 2A-2D.

During manufacture of the semiconductor device according to the present embodiment example, first, a silicon substrate 11 is prepared, and a shallow trench isolation (STI) 12 is formed on this silicon substrate to form an active region 13 surrounded by the STI 12 (FIG. 2). Although several active regions are formed on the actual silicon substrate 11, FIG. 2 shows only two active regions 13A and 13B. Although not specifically limited, the active regions 13A and 13B in the present embodiment example are both rectangular in shape.

During formation of the STI 12, a trench having a depth of about 220 nm is formed in the principal plane of the silicon substrate 11 by dry etching, a thin silicon oxide film is formed over the entire surface of the substrate including the inside wall of the trench by thermal oxidation at about 1000° C., then a silicon oxide film having a thickness of 400-500 nm is accumulated by chemical vapor deposition (CVD) over the entire surface of the substrate including the inside of the trench. Subsequently, unnecessary silicon oxide film on the silicon substrate 11 is removed by chemical mechanical polishing (CMP) to leave the silicon oxide film only inside the trench forming the STI 12.

Next, silicon pillars 15A and 15B are formed simultaneously inside the active region 13A and 13B, respectively. The silicon pillars 15A and 15B are portions comprising pillar Tr channels, and may be of any number provided that there are at least two. The present embodiment example, however, will be described for a case in which three pillar Tr are formed in one active region. During formation of the silicon pillars 15A and 15B, first, a silicon oxide film 14a comprising a protective insulating film is formed over the entire surface of the substrate, a resist R is applied and patterned by lithography for each of the active regions 13A and 13B, and an impurity such as boron is introduced by injection so as to produce the impurity concentration required for each pillar Tr.

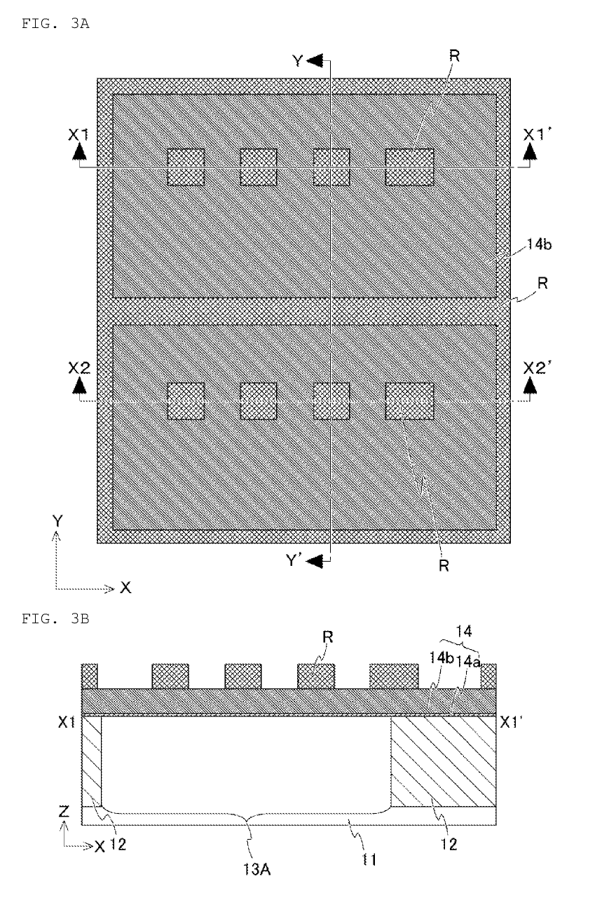

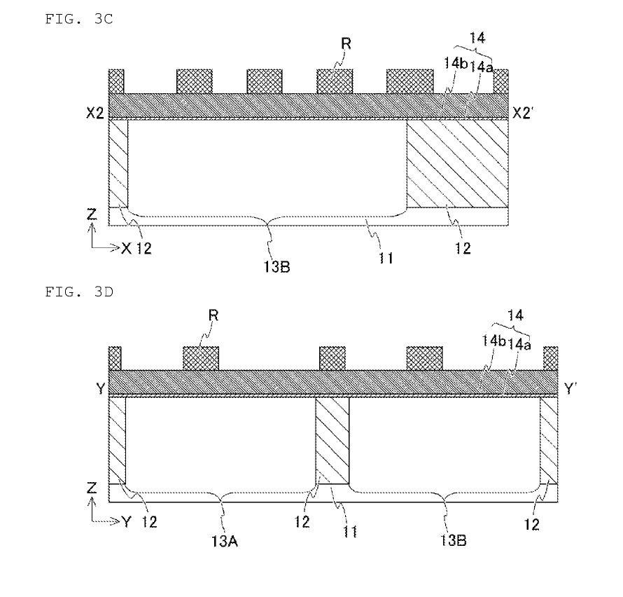

Next, a silicon nitride film 14b comprising a hard mask is formed over the entire surface of the substrate. Although not specifically limited, the silicon oxide film 14a and the silicon nitride film 14b may be formed by CVD. The thickness of the silicon oxide film 14a is preferably about 5 nm, and the thickness of the silicon nitride film 14b is preferably about 120 nm. In the present embodiment example, the laminated films of the silicon oxide film 14a and the silicon nitride film 14b are sometimes simply called a ‘hard mask’ 14. As shown in FIG. 3, the hard mask 14 is processed by a photolithographic technique to form a resist mask R of a predetermined pattern on the silicon nitride film 14b. Resist masks are formed on the active regions 13A and 13B so as to produce the same pillar diameter. Resist masks R may also be formed, however, so as to produce different pillar diameters.

Subsequently, the hard mask 14 is patterned so as to leave the hard mask 14 in the region where the silicon pillars 15A and 15B will be formed and a region on the outside of the active region 13, and to remove the hard mask everywhere else. The edges of the hard mask 14 covering the STI 12 are preferably located somewhat more to the outside of the active regions 13A and 13B so as not to form unnecessary silicon pillars inside the active regions 13A and 13B.

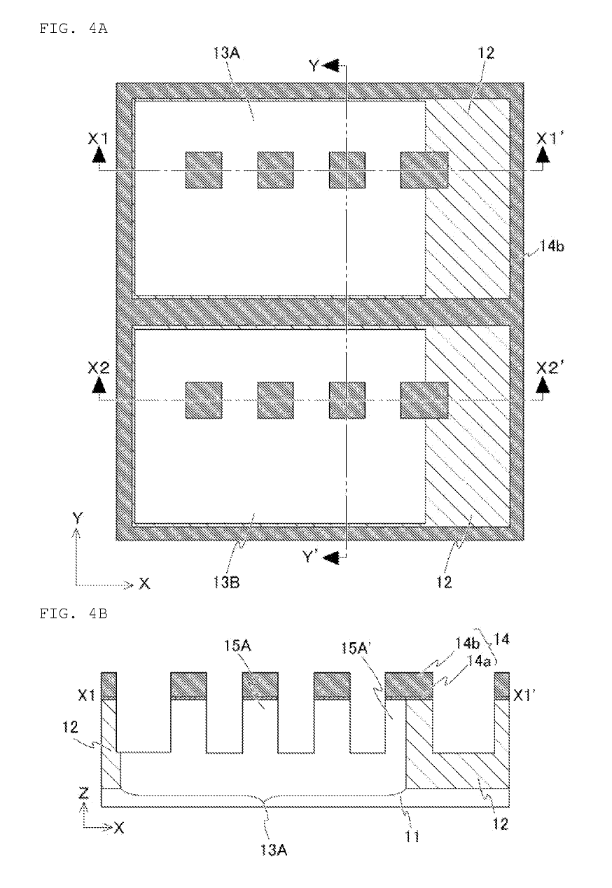

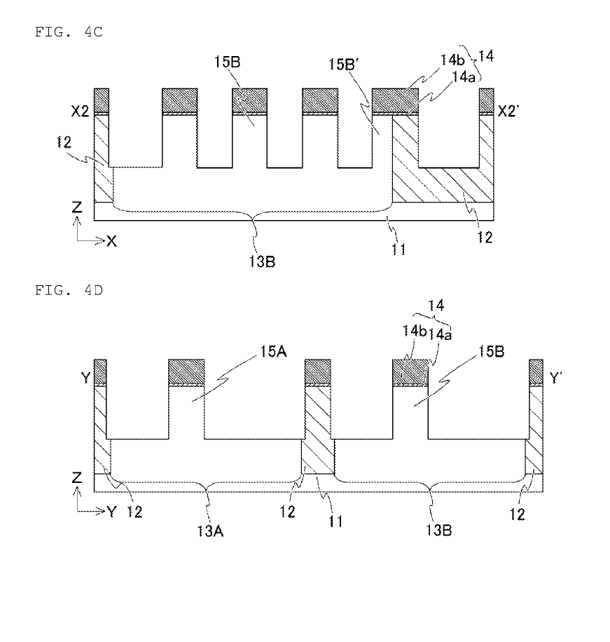

The hard mask 14 patterned in this way is used to dig out the exposed surface of the active regions 13A and 13B and the STI 12 by dry etching. This dry etching process forms a depression in the exposed surface of the active regions 13A and 13B, and the portion not dug out becomes nearly vertical silicon pillars 15A and 15B on the principal plane of the silicon substrate (FIG. 4). The hard mask 14 left on the upper portions of the silicon pillars 15A and 15B becomes cap insulating films. A portion of the active regions 13A and 13B contacting the STI 12 is left as dummy pillars 15A′ and 15B′ for gate feeding. The plurality of silicon pillars 15A and 15B are formed leaving predetermined spaces in between. These spaces will be connected to each other to form a continuous space by a gate electrode 20 formed in a later process, and are preferably formed so as to be at least the film thickness of the gate electrode 20 and less than twice the film thickness of the gate electrode.

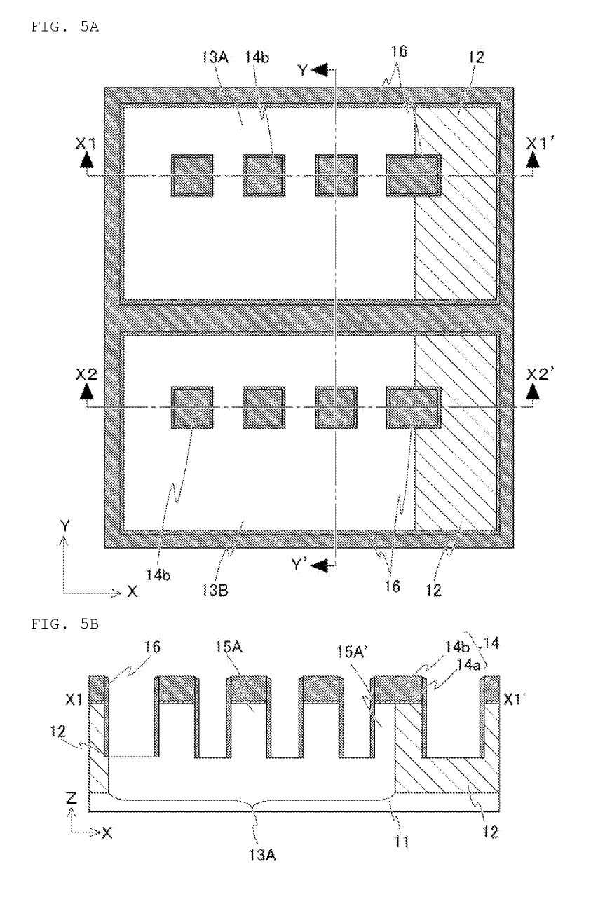

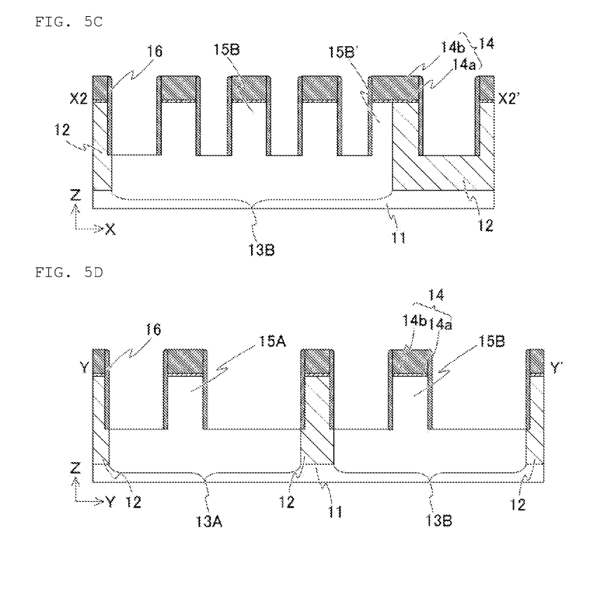

Next, a sidewall insulating film 16 is formed on the sides of the silicon pillars 15A and 15B (FIG. 5). The sidewall insulating film 16 may be formed by using thermal oxidation to protect the exposed surface of the silicon substrate 11 with the hard mask 14 left intact, then forming a silicon nitride film and etching this silicon nitride film. As a result, the sidewall insulating film 16 covers the inner circumferential surfaces of the active regions 13A and 13B (the side walls of the STI 12) and the sides of the silicon pillars 15A and 15B.

Next, a silicon oxide film 17 is formed on the exposed surface of the silicon substrate 11 (that is, the floors of the active regions 13A and 13B) (FIG. 6). During this formation, the top face and sides of the silicon pillars 15A and 15B are not thermally oxidized because the top face is covered by the hard mask 14 forming a cap insulating film and the sides are covered by the sidewall insulating film 16. Although not specifically limited, the thickness of the silicon oxide film 17 is preferably about 30 nm.

Next, a first diffusion layer 18 is formed on a lower portion of the silicon pillars 15A and 15B (FIG. 7). The first diffusion layer 18 may be formed through the silicon oxide film 17 formed on the surface of the active regions 13 by injecting ions of an impurity having the opposite conductivity type to the impurity in the silicon substrate (channel). Because the P-type impurity of boron was injected in the channel earlier, an opposite N-type impurity, such as phosphorus or arsenic, is injected during this process.

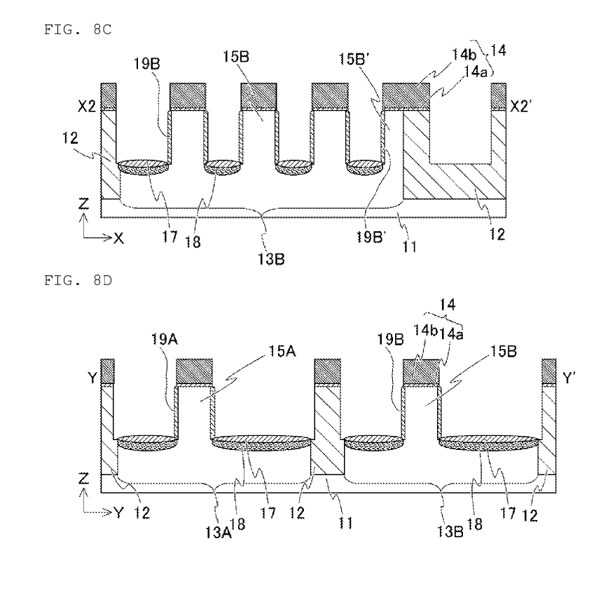

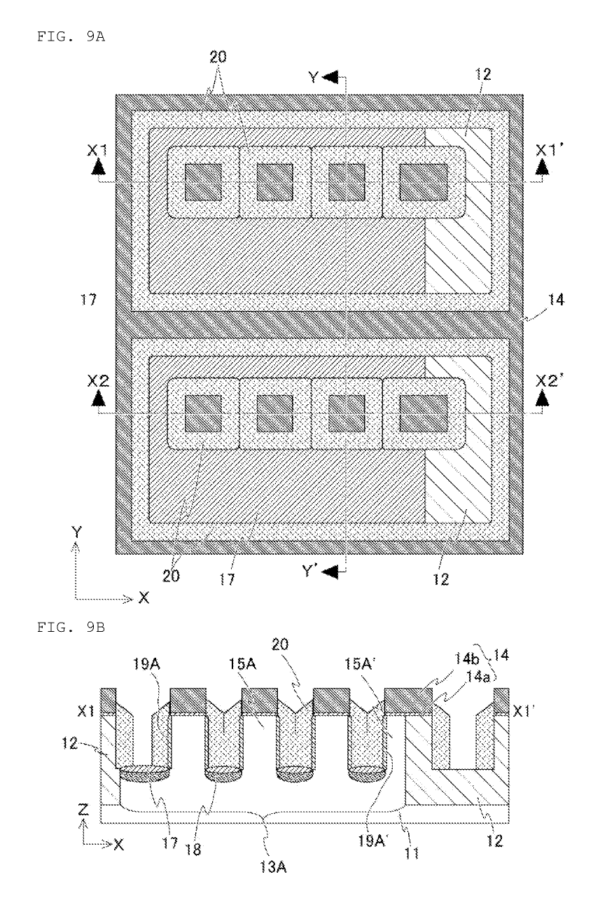

Next, the sidewall insulating film 16 is removed by wet etching, then gate insulating films 19A and 19B are formed simultaneously on the sides of the silicon pillars 15A and 15B leaving the hard mask 14 intact (FIG. 8). The gate insulating films 19A and 19B may be formed by thermal oxidation. The films have nearly the same thickness, preferably about 5 nm. During this formation, dummy gate insulating films 19A′ and 19B′ are formed on the surfaces of the dummy silicon pillars 15A′ and 15B′.

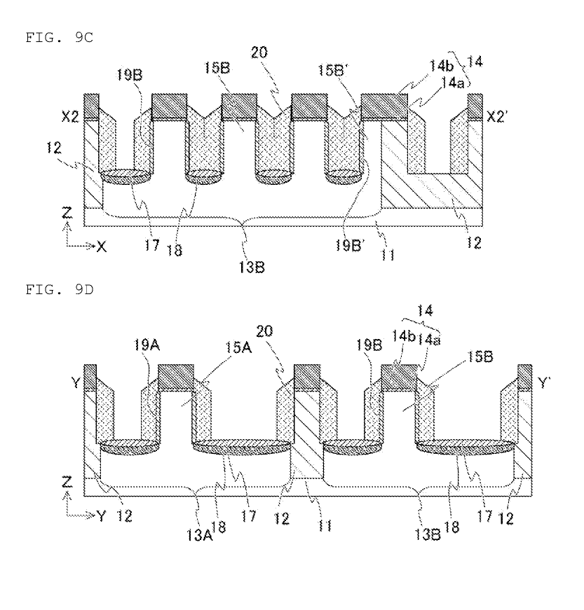

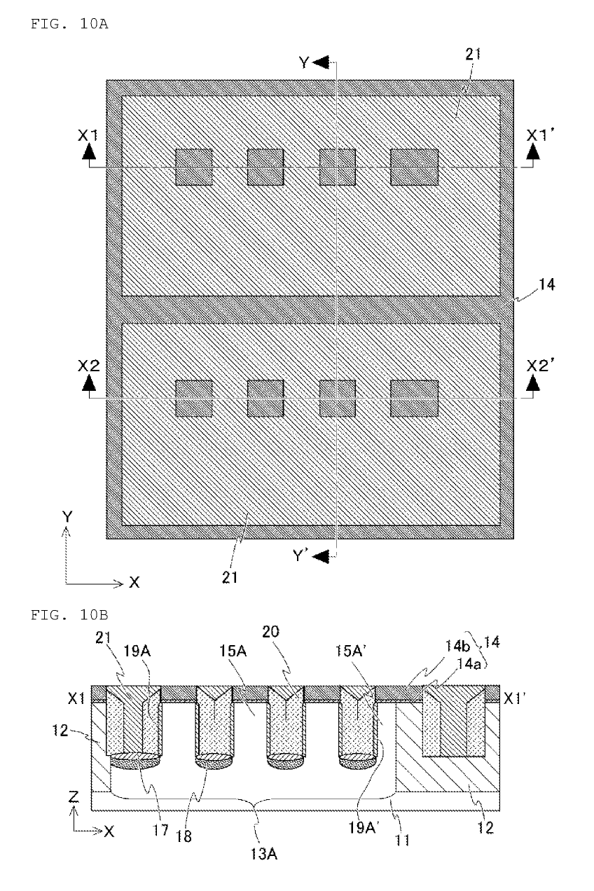

Next, a gate electrode 20 comprising a polysilicon film is formed (FIG. 9). The gate electrode 20 may be formed by forming a conformal coating of a polysilicon film having a thickness of about 30 nm by CVD over the entire surface of the substrate leaving the hard mask 14 intact, then etching back the polysilicon film as far as a location lower than the top face of the hard mask 14. As a result, the gate electrode 20 covers the sides of the silicon pillars 15A and 15B, and the gaps between the silicon pillars 15A are set at less than twice the thickness of the gate electrode 20. Therefore, the gate electrodes 20 formed in the gaps between the silicon pillars 15A in the linear direction are connected to each other. The space between the dummy pillar 15A′ and the adjacent silicon pillar 15A is also set at less than twice the thickness of the gate electrode 20, and the gate electrode 20 between the two pillars is connected to the other gate electrodes. The gate electrode 20 formed in the space between the dummy pillar 15B′ and the adjacent silicon pillar 15B is likewise connected to the other gate electrodes. Although a polysilicon film is also left on the sides of the STI 12 on the peripheral edges of the active regions 13A and 13B, this polysilicon film does not function as a gate electrode.

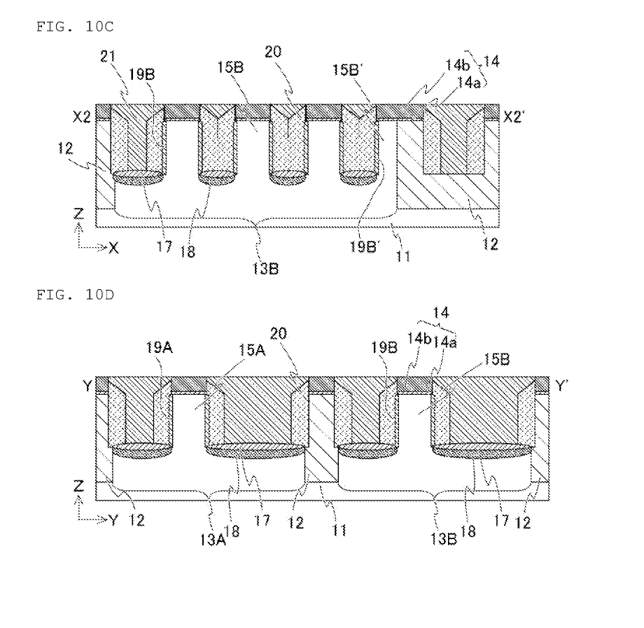

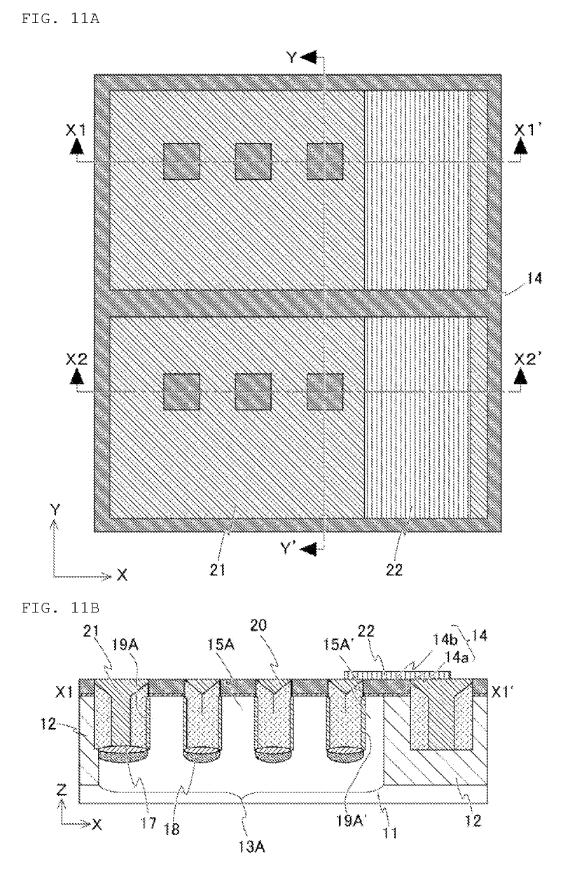

Next, an interlayer insulating film 21 comprising a silicon oxide film is formed over the entire surface of the substrate, then the surface of the interlayer insulating film 21 is flattened by grinding using CMP (FIG. 10). The thickness of the interlayer insulating film 21 can be accurately controlled during this process because the silicon nitride film 14b plays the role of a CMP stopper. Thus, the interlayer insulating film 21 buries the inside of the active regions 13A and 13B.

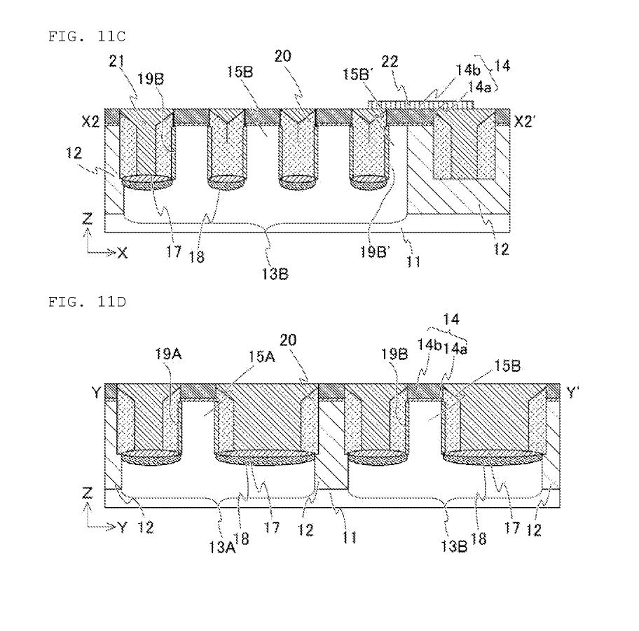

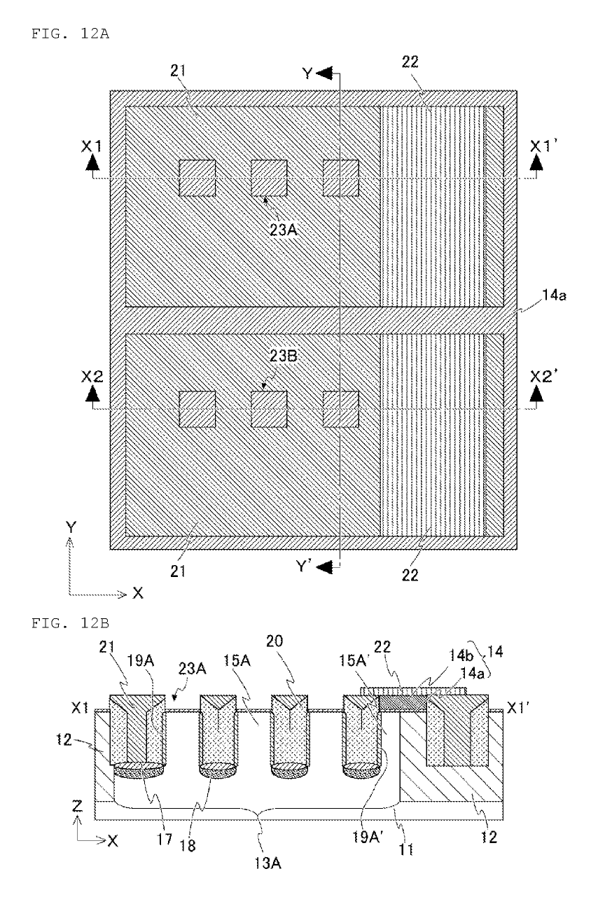

Next, a mask oxide film 22 is formed to protect the hard mask 14 on the upper portions of the dummy silicon pillars 15A′ and 15B′ (FIG. 11). First, a mask oxide film 22 comprising a silicon oxide film may be formed over the entire surface of the substrate by CVD. The thickness of the mask oxide film 22 is preferably about 5 nm. Next, the mask oxide film 22 is patterned so as to expose the silicon nitride film 14b formed above the silicon pillars 15A and 15B, and protect the silicon nitride film 14b above the dummy silicon pillars 15A′ and 15B′.

Subsequently, the exposed silicon nitride film 14b is removed by dry etching or wet etching to form through-holes 23A and 23B comprising the floor of the silicon oxide film 14a forming a protective insulating film above the silicon pillars 15A and 15B (FIG. 12). Because the through-holes 23A and 23B are formed by removing the silicon nitride film 14b used as a mask during formation of the silicon pillars 15A and 15B, the through-holes are formed self-aligned with the silicon pillars 15A and 15B. Therefore, in plan view, the sides of the through-holes 23A and 23B match the outer circumferential portions of the silicon pillars 15A and 15B. The outer circumferential portions and the silicon nitride film 14b between the active regions 13A and 13B are also removed.

Next, an LDD region 24 is formed on the upper portions of the silicon pillars 15A and 15B (FIG. 13). The LDD region 24 may be formed by injecting ions having a low concentration of an impurity, having the opposite conductivity type to the impurity in the channel, from the through-holes 23A and 23B formed on the upper portions of the silicon pillars 15A and 15B and through the silicon nitride film 14a. The silicon nitride film 14b is left on the dummy silicon pillars 15A′ and 15B′, and no LDD region is formed.

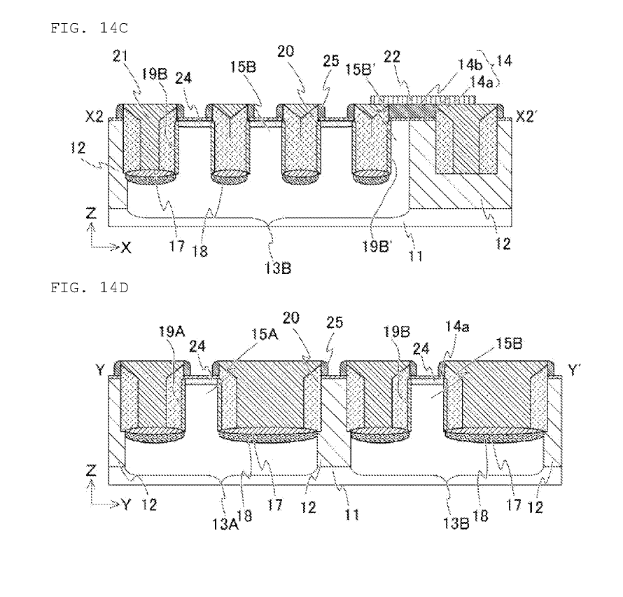

Next, a sidewall insulating film 25 is formed on the inner walls of the through-holes 23A and 23B (FIG. 14). The sidewall insulating film 25 may be formed by forming a silicon nitride film over the entire surface of the substrate, then etching this film. Although not specifically limited, the thickness of the silicon nitride film is preferably about 10 nm. Thus, the sidewall insulating film 25 is formed on the inner walls of the through-hole 23, and the through-hole 23 is formed by removing the silicon nitride film 14b comprising a hard mask used during formation of the silicon pillars 15A and 15B. Therefore, in plan view, the outer circumferential portion of the tubular sidewall insulating film 25 matches the outer circumferential portion of the silicon pillars 15A and 15B. Although a silicon nitride film is also formed on the outer peripheral surface of the active regions 13A and 13B, this silicon nitride film does not function as a sidewall insulating film.

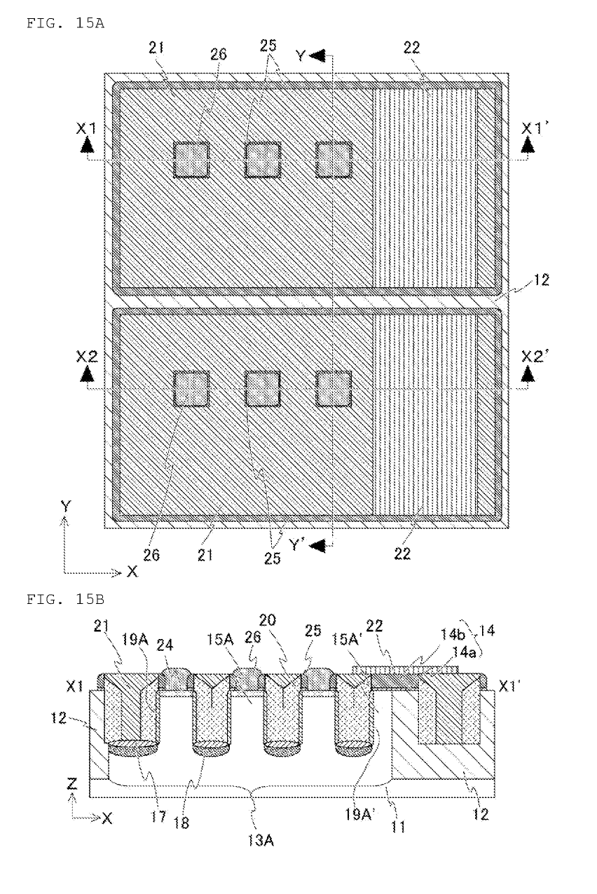

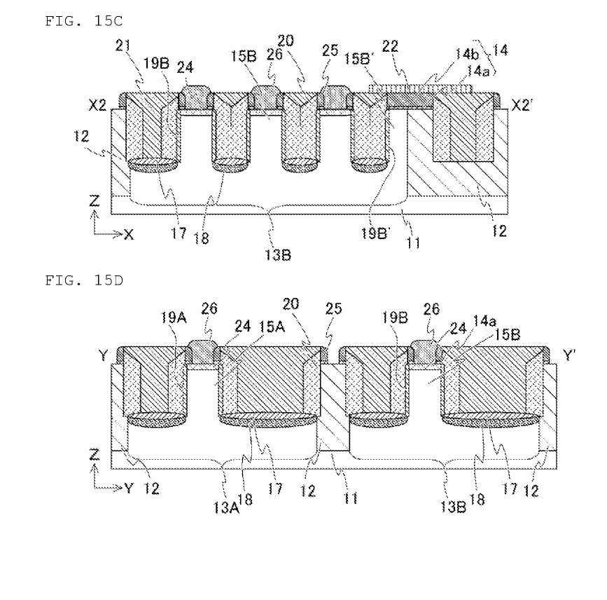

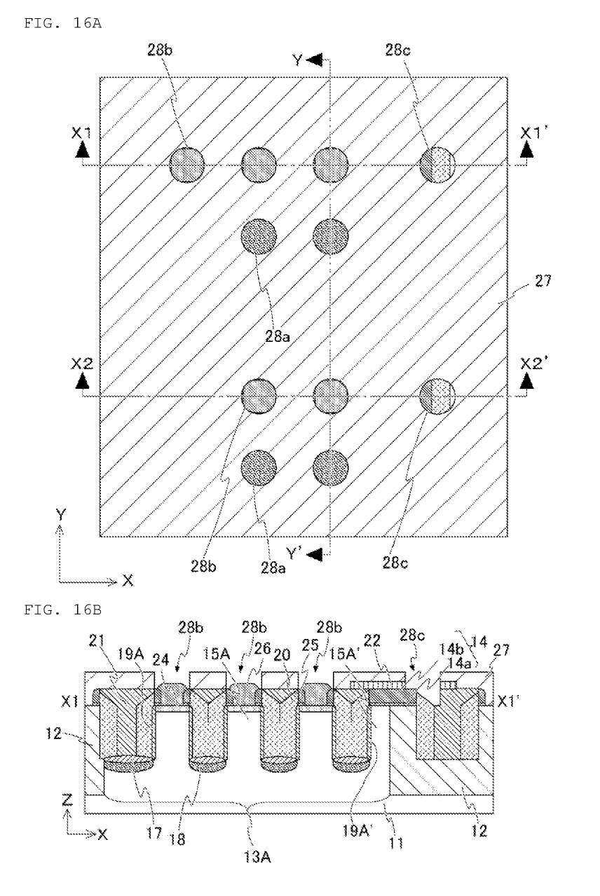

Next, a second diffusion layer 26 is formed on the upper portions of the silicon pillars 15A and 15B. During formation of the second diffusion layer 26, first, the through-hole 23 is dug out to make an opening in the silicon oxide film 14a on the floor of the through-hole, exposing the top face of the silicon pillars 15A and 15B. A silicon epitaxial layer is then formed inside the through-hole 23 by selective epitaxial growth. As a result, nearly monocrystalline silicon is grown. Subsequently, the second diffusion layer 26 is formed by injecting a high concentration of ions of an impurity having the opposite conductivity type to the impurity in the silicon substrate into the silicon epitaxial layer at a higher concentration than the LDD region 24 (FIG. 15). As a result, the second diffusion layer 26 is formed self-aligned with the silicon pillars 15A and 15B.

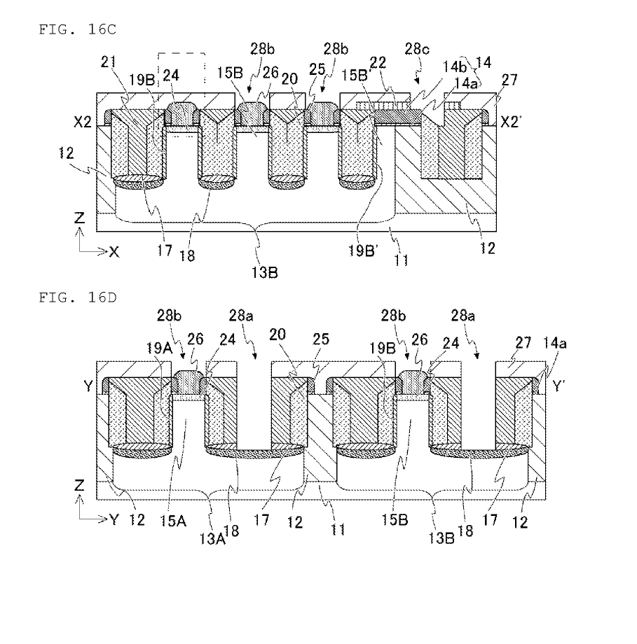

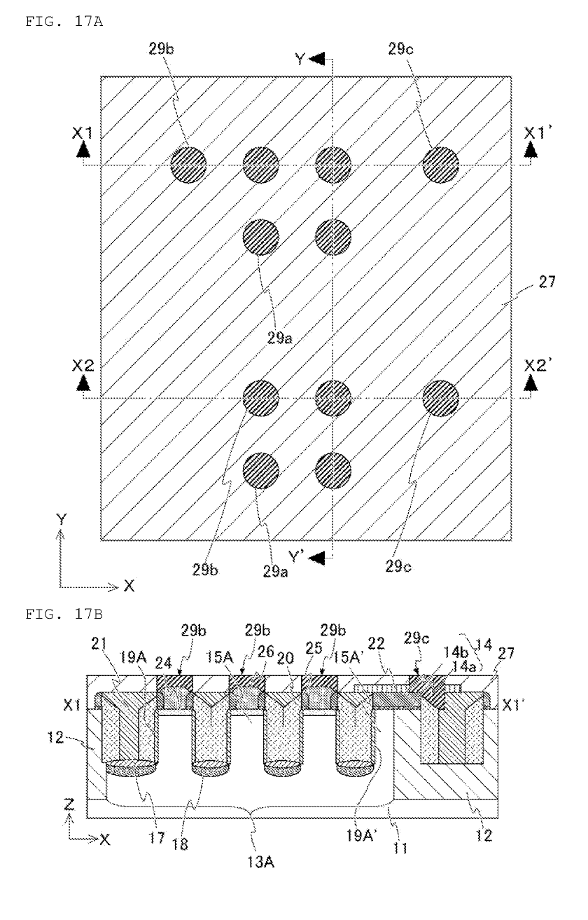

Next, an interlayer insulating film 27 is formed over the entire surface of the substrate, then patterned to form contact holes 28a, 28b, and 28c (FIG. 16). The contact hole 28a is formed in an empty region in the active regions 13A and 13B disposed next to the silicon pillars 15A and 15B, and extends through the interlayer insulating films 27, 21, and 17 to reach the first diffusion layer 18. The contact hole 28b is formed directly over the silicon pillars 15A and 15B, and extends through the interlayer insulating film 27 to reach the second diffusion layer 26. Among the silicon pillars 15B, however, the contact hole 28b is not formed directly over the third silicon pillar 15B most distant from the contact hole 28c for gate feeding. The contact hole 28c is not formed directly over the dummy silicon pillars 15A′ and 15B′, but above the STI 12 contacting the dummy pillars 15A′ and 15B′, and extends through the interlayer insulating film 27, the mask oxide film 22, and the interlayer insulating film 21 to reach the gate electrode 20 formed on the perimeter of the dummy pillars 15A′ and 15B′. In particular, the contact hole 28c is preferably connected to a position opposite the silicon pillars 15A and 15B within the gate electrodes 20 formed on the perimeter of the dummy pillars 15A′ and 15B′. Connecting in this way can widen the space between the contact hole 28b and the contact hole 28c, thus ensuring a sufficient margin.

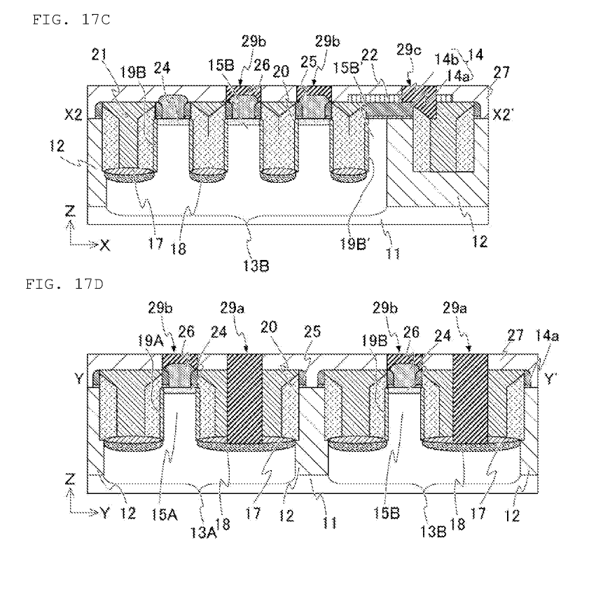

Next, polysilicon is buried inside the contact holes 28a, 28b, and 28c to form contact plugs 29a, 29b, and 29c (FIG. 17). The contact plug 29a is connected to the first diffusion layer 18, the contact plug 29b is connected to the second diffusion layer 26, and the third contact plug 29c is connected to the gate electrode 20.

Finally, a layout layer 30 is formed on upper portions of the contact plugs 29a, 29b, and 29c to complete the semiconductor device according to the present embodiment example (FIG. 1).

Although a method for manufacturing a preferred embodiment of the present invention has been described, the present invention is not limited to this embodiment, and various modifications may be possible without departing from the scope of the present invention, all of which, needless to say, are included in the present invention.

For example, dummy pillars 15A′ and 15B′ were disposed next to the silicon pillars 15A and 15B comprising transistor pillars in the embodiment, but disposing such dummy pillars is not essential in the present invention.

Although all of the silicon pillars in the embodiment are square in shape and have a similar planar shape, the present invention is not limited to such a configuration, and various shapes may be considered. For example, silicon pillars having a long and narrow rectangular shape in the planar direction or silicon pillars having another planar shape such as round, elliptical, or polygonal may be used.

Although a silicon epitaxial layer was formed in a through-hole in the embodiment and this silicon epitaxial layer was injected with ions to form the second diffusion layer 26, the present invention is not limited to such a process. For example, a polysilicon layer doped with an impurity may be buried in the through-hole to form the second diffusion layer 26 (which may also be used as a contact plug). Using selective epitaxial growth, however, ensures the continuity of the crystal, making it possible to obtain better transistor characteristics. Although the silicon pillars 15A and 15B and the second diffusion layer 26 were configured in different areas in the embodiment, the second diffusion layer 26 may be formed on an upper portion of the silicon pillars 15A and 15B.

Thus, according to the present invention, the number of parallel-connected silicon pillars can be adjusted by changing the number of contact holes 28b in the final stage, and a plurality of pillar transistors having different transistor characteristics can be formed. Circuit characteristics can also be adjusted by adjusting the number of parallel-connected silicon pillars.

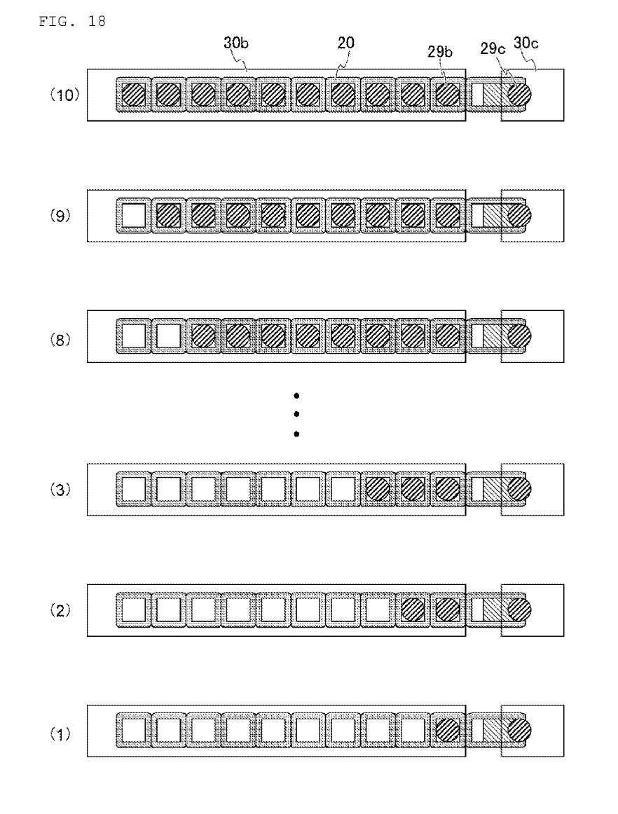

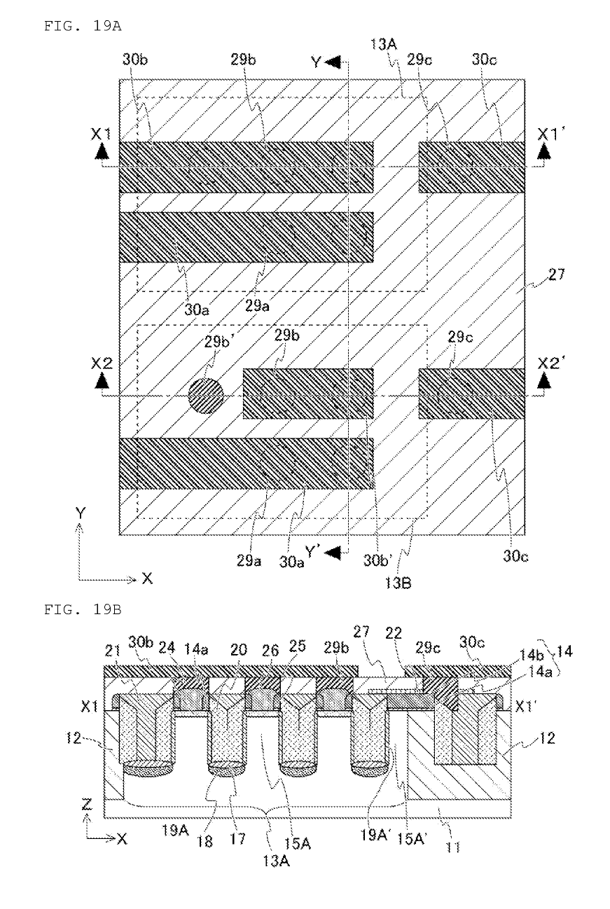

For example, FIG. 18 shows a case in which ten silicon pillars were formed in one active region. If the drive current when all ten pillars are connected is taken as 100%, the drive current can be adjusted in stages of 10% from 10% to 90% by changing the number of connections from one to nine. The manner of connecting in parallel is not limited to arranging silicon pillars in a row within one active region, and pillars may be arranged in a plurality of rows to adjust the number of connections.

In the case that the size of the silicon pillar at the outermost end of the gate (most distant from the contact plug 29c) among the parallel-connected silicon pillars is subject to the greatest variance in terms of pillar transistor manufacturing tolerance and the ON current is subject to variance, the present invention may be applied to make the silicon pillar at the outermost end of the gate a dummy pillar to minimize the effect of manufacturing tolerance. This pillar made a dummy pillar differs from the dummy pillar 15B′ formed for gate feeding on the point that a second diffusion layer 26 is formed on an upper portion of the pillar. Although the silicon pillar made a dummy pillar in this way cannot be used for gate feeding, contact between the contact 29c for gate feeding and the second diffusion layer 26 must be avoided in this case.

In the case that readjusting transistor characteristics is desired after the design has been completed, the reticle for correcting may be only one contact reticle for connecting to an upper portion of each silicon pillar, and the reticle need not be modified during the first process (formation of element separation regions and pillars) of the manufacturing process. When compared to a planar transistor, increase in the chip size due to arranging excess transistors can be minimized because the dedicated area can be largely determined at the first design stage.

### Embodiment Example 2

In the Embodiment Example 1, a method of adjusting transistor characteristics by modifying formation of the contact hole 28b in the final stage was described. The number of connections may also be modified, however, by forming the contact hole 28b and the contact plug 29b on all of the silicon pillars, then patterning the layout layer 30.

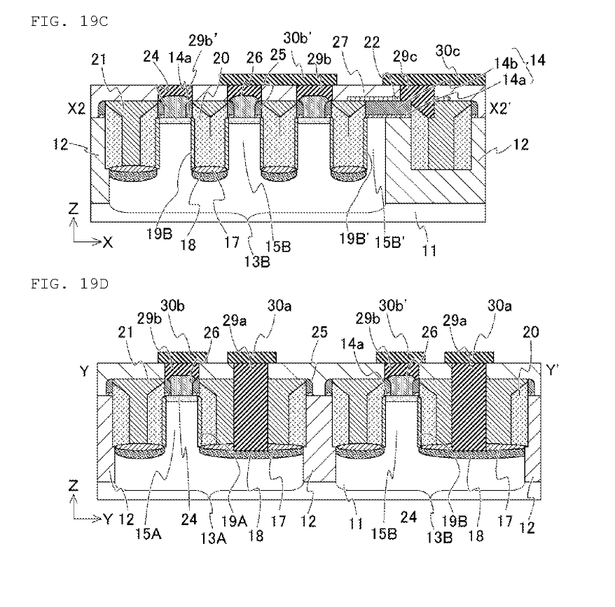

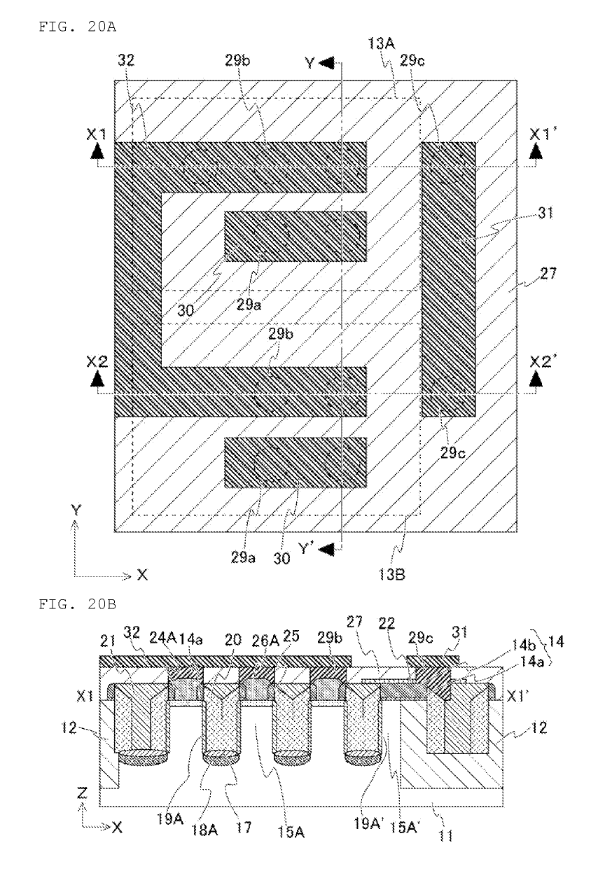

FIG. 19A shows a plan view of the manufacturing process of a semiconductor device according to the present embodiment example of the present invention. FIG. 19B shows a sectional view taken at X1-X1′ in FIG. 19A, FIG. 19C shows a sectional view taken at X2-X2′ in FIG. 19A, and FIG. 19D shows a sectional view taken at Y-Y′ in FIG. 19A.

With the present embodiment example, contact plugs through the contact plug 29b are formed on all of the silicon pillars 15B in the same manner as the silicon pillars 15A, and the number of pillars for connecting in parallel is adjusted by changing the length of the layout 30b.

Thus, the number of pillars for connecting in parallel can be adjusted by changing the length of the layout 30b, and if a readjustment is required, only the pattern of the final layout 30b need be changed. Therefore, the reticle for correcting need only be one reticle for the final layout pattern. In the case that the number of silicon pillars formed for two pillar transistors has some margin, making the number of contact plugs 29b formed different for each transistor as in Embodiment Example 1 may be combined with the method of changing the length of the layout 30b according to the present embodiment example.

### Embodiment Example 3

An example of forming a CMOS inverter with the same configuration as Embodiment Example 1 will be described as Embodiment Example 3.

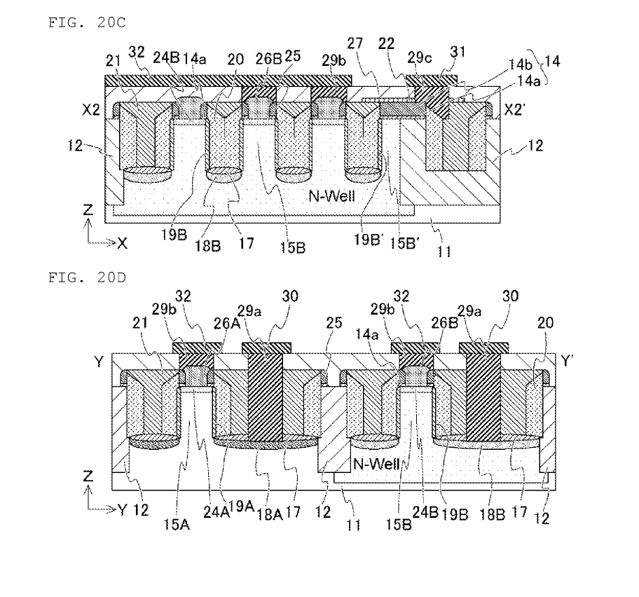

FIG. 20A shows a plan view of the manufacturing process of a semiconductor device according to the present embodiment example of the present invention. FIG. 20B shows a sectional view taken at X1-X1′ in FIG. 20A, FIG. 20C shows a sectional view taken at X2-X2′ in FIG. 20A, and FIG. 20D shows a sectional view taken at Y-Y′ in FIG. 20A.

In this case, an NMOS transistor is formed in the active region 13A, a PMOS transistor is formed in the active region 13B, an inter-gate layout 32 connects gate electrodes 20, and an inter-drain layout 31 connects drain regions (second diffusion layers 26A and 26B). With the present embodiment example, a p-type silicon substrate 1 is used as a semiconductor substrate, an N-well is formed in the active region 13B, an n-type impurity is introduced into a first diffusion layer 18A, an LDD region 24A, and a second diffusion layer 26A formed in the active region 13A, and a p-type impurity is introduced into a first diffusion layer 18B, an LDD region 24B, and a second diffusion layer 26B formed in the active region 13B. Silicon pillars 15A and 15B surrounded by a gate electrode 20 comprising a channel are also of different conductivity types. An impurity of a different conductivity type may also be introduced in the gate electrode 20.

Thus, the performance can be finely adjusted in a CMOS inverter by changing the number of pillar connections between an NMOS transistor and a PMOS transistor. The number of pillar connections may also be adjusted by patterning the inter-drain layout 31 as shown in Embodiment Example 2.

Although the above description was described for a surrounding gate pillar transistor in which the gate electrode 20 surrounds the side circumference of the silicon pillars, the present invention is not limited to this configuration. The present invention may be applied in the same manner to a single-gate pillar transistor in which a gate electrode opposes one side of each silicon pillar through a gate insulating film, or a double-gate pillar transistor in which two gate electrodes oppose opposite sides of each silicon pillar.

### EXPLANATION OF REFERENCE NUMBERS

11 Silicon substrate
12 STI
13A, 13B Active region
14 Hard mask
14a Silicon oxide film (mask insulating film)
14b Silicon nitride film (cap insulating film)
15 Silicon pillar
15A, 15B Silicon pillar
15A′, 15B′ Silicon pillar (dummy)
16 Sidewall insulating film
17 Silicon oxide film
18 First diffusion layer
18A n-type First diffusion layer
18B p-type First diffusion layer
19 Gate insulating film
20 Gate electrode
21 Interlayer insulating film
22 Mask oxide film
23 Through-hole
24 LDD region
24A n-type LDD region
24B p-type LDD region
25 Sidewall insulating film
26 Second diffusion layer
26A n-type Second diffusion layer
26B p-type Second diffusion layer
27 Interlayer insulating film
28a Contact hole
28b Contact hole
28c Contact hole
29a Contact plug
29b Contact plug
29c Contact plug
30 Layout (conductive layer)
30a Layout comprising source electrode
30b Layout comprising drain electrode
30c Gate layout
31 Layout between gates
32 Layout between drains

1. A semiconductor device comprising:
at least two pillar transistors raised in mutually isolated element regions on a semiconductor substrate, wherein the two pillar transistors comprise:
the same number of two or more pillars in each of the element isolated regions;
a diffusion layer arranged on an upper portion of each of the pillars; and
a conductive layer electrically connected to the diffusion layer in each of the element isolated regions; and
the two pillar transistors differ from each other in the number of diffusion layers electrically connected to the conductive layer.

2. The semiconductor device of claim 1, wherein the conductive layer in each of the element isolated regions is arranged so as to pass above all of the pillars, and the two pillar transistors differ from each other in the number of contacts for connecting the diffusion layer to the corresponding conductive layer.

3. The semiconductor device of claim 1, wherein the two pillar transistors have a contact connected to each of the diffusion layers on an upper portion of a pillar in each of the element isolated regions, and differ from each other in the number of connections between the corresponding conductive layer and the contacts.

4. The semiconductor device of claim 1, wherein the two pillar transistors are provided with a gate electrode comprising a connector through a gate insulating film on the sides of all of the pillars in each of the element isolated regions.

5. The semiconductor device of claim 1, wherein the channels included in the pillars in each of the element isolated regions in the two pillar transistors are of different conductivity types from each other, and each of the diffusion layers has the opposite conductivity type to the corresponding channel.

6. The semiconductor device of claim 5, wherein at least the conductive layers of the two pillar transistors are connected to each other to comprise a CMOS inverter circuit.

7. The semiconductor device of claim 1, wherein the top faces of the pillars of the two pillar transistors are formed at a nearly equal height to the top face of the element isolation insulating layer.

8. The semiconductor device of claim 1, wherein the top face of the diffusion layer is located above the top face of the pillars.

9. A semiconductor device comprising:
a plurality of pillar transistors raised on a semiconductor substrate;
a plurality of source regions, a plurality of channel regions, and a plurality of drain regions comprising each of the plurality of pillar transistors;
a source electrode for connecting to each of the plurality of source regions;
a gate electrode for simultaneously driving each of the channel regions;
a drain electrode connected through a contact to a portion of the plurality of drain regions; and
at least one drain region of the plurality of drain regions for opposing the drain electrode not through the contact, but through an insulating layer.

10. The semiconductor device of claim 9, wherein the plurality of pillar transistors are formed in one element isolated region.

11. The semiconductor device of claim 10, wherein the plurality of pillar transistors have, in the one element isolated region, a plurality of pillars including the channel regions, a diffusion layer region connecting the plurality of source regions to each other in a lower portion of the plurality of pillars, and the plurality of drain regions on an upper portion of each of the plurality of pillars.

12. The semiconductor device of claim 10, wherein the plurality of pillar transistors form a connector by contacting the gate electrodes to each other.

13. The semiconductor device of claim 11, wherein the gate electrode is formed so as to surround the side circumference of the pillars, and the plurality of pillars are arranged with a predetermined space in between so as to form a connector by contacting each of the gate electrodes to each other.

14. A semiconductor device comprising:
a plurality of pillar transistors raised on a semiconductor substrate;
each of the plurality of pillars has a lower portion, an upper portion, and sides;
the device is provided with a first diffusion layer for connecting to each of the lower portions;
a plurality of second diffusion layers arranged on each of the upper portions;
a gate electrode comprising a connector and opposing a gate insulating film on each of the sides;
a conductive layer electrically connected to one or more of the plurality of second diffusion layers; and
one or more contacts formed on one or more of the plurality of second diffusion layers;
and the number of electrical connections between the second diffusion layers and the conductive layer is less than the number of the pillars.

15. The semiconductor device of claim 14, wherein the conductive layer is arranged so as to pass above all of the pillars, and the number of contacts for connecting the second diffusion layer to the conductive layer is less than the number of pillars.

16. The semiconductor device of claim 14, wherein the contact is connected above all of the plurality of pillars, and the number of connections between the conductive layer and the contact is less than the number of the pillars.

17. The semiconductor device of claim 14, wherein the plurality of pillars are formed in one element isolated region.

18. The semiconductor device of claim 17, wherein the gate electrode is formed so as to surround the side circumference of the pillars, and the plurality of pillars are arranged with a predetermined space in between so as to form a connector by contacting each of the gate electrodes to each other.
